(19) United States
(12) Patent Application Publication
(10) Pub. No.: US 2019/0371942 A1
(43) Pub. Date: Dec. 5, 2019

(54) SEMICONDUCTOR DEVICE STRUCTURE AND METHOD OF FORMING SUCH A SEMICONDUCTOR DEVICE STRUCTURE

(71) Applicant: GLOBALFOUNDRIES Inc., Grand Cayman (KY)

(72) Inventors: Germain Bossu, Dresden (DE); Sylvain Henri Baudot, Dresden (DE)

(21) Appl. No.: 15/992,358

(22) Filed: May 30, 2018

(51) Int. Cl. H01L 29/78; H01L 29/51; H01L 29/66; H01L 21/28

(52) U.S. Cl. CPC H01L 29/78391; H01L 21/28088; H01L 29/6684; H01L 29/516

(57) ABSTRACT

The present disclosure provides a semiconductor device structure and a method of forming such a semiconductor device structure. The semiconductor device structure disclosed herein includes a semiconductor substrate having a first active region formed therein and a first gate structure formed over the first active region. The first active region has a doping of a first conductivity type and the gate structure includes a first ferroelectric material and a first gate electrode, wherein the first gate electrode has a first work function of the first conductivity type.

### BACKGROUND

### 1. Field of the Disclosure

The present disclosure relates to the fabrication of semiconductor device structures and, more particularly, to ferroelectric field effect transistor (FeFET) structures and methods of forming such structures.

### 2. Description of the Related Art

An increasing demand for more mobility, high integration density and low power consumption drives the development of complex electronic devices to an increasing interest in the flash memory technique. Opposed to volatile memory, e.g., DRAM, where a stored memory state has to be refreshed after a given time and stored data are lost once the power supply is switched off, flash memory has gained an increasing interest as it is a so-called non-volatile memory. This is, for example, visible in the market of flash memory technologies which rapidly increased from a share in the market of 11% in 1998 to more than 32% in 2006, whereas the share of DRAM technology in the market decreased from 60% to 56% and continues to shrink. Due to the unchallenged performance advantages of non-volatile memories over current technologies with regard to write endurance, write voltage and power consumption, this tendency is not expected to change.

Flash memory, representing a popular example of an electronic non-volatile computer storage medium that can be electrically erased and reprogramed, storing information in an array of memory cells, is made from floating gate transistors or by employing ferroelectrics. The latter raised an increasing interest in the development of ferroelectric FETs (FeFETs) which are currently considered a promising candidate allowing following the roadmap in the deep sub-micron region to 22 nm and beyond, although FeFETs have not yet left the research and development stage.

The basic idea of a FeFET is to take an existing logic transistor with a high-k/metal gate stack based on hafnium oxide and then to modify the gate insulator with ferroelectric properties. The resulting structure is the same transistor with a scalable embedded FeFET memory with low power and non-volatile properties. The efforts in current research and development aim at out-performing today's embedded flash memories by FeFETs. Although it sounds like a simple concept of applying FeFET to non-volatile device applications, there are several challenges that have to be addressed and that FeFETs are currently faced with, such as integration issues, data retention, reliability and cost, on top of the issues that arise with respect to existing memory solutions when matching Moore's law. For example, current embedded NVM technology is dominated by embedded NOR-type flash memory, which becomes more expensive when scaling to more advanced process nodes. For example, one challenge when looking at the transition happening at 32 nm to 22 nm is to make regular logic transistors and flash devices co-existent on the same substrate.

With regard to FIGS. 1a-1c, the function of a known FeFET will be explained in greater detail. FIGS. 1a and 1b show a FeFET 10 having a gate structure 20 formed over a semiconductor substrate 1 and covering a channel region 3 provided between source/drain regions 5. The source/drain regions 5 are aligned with the gate structure 20. The gate structure 20 of the FeFET comprises a gate stack composed of silicon oxide 22 covering the semiconductor substrate 1 over the channel region 3, a ferroelectric hafnium oxide layer 24 formed on the silicon oxide 22, and a gate electrode 26 formed on the ferroelectric hafnium oxide layer 24. The sidewalls of the gate stack are covered by sidewall spacers 28.

The ferroelectric hafnium oxide layer 24 has the property that a permanent dipole moment is formed within the ferroelectric hafnium oxide layer 24 depending on a voltage applied to the gate electrode 26. Particularly, FIG. 1a shows the FeFET 10 in a state where a permanent polarization P1 is present in the ferroelectric hafnium oxide layer 24, while FIG. 1b shows the FeFET 10 in a state where a permanent polarization P2 is present in the ferroelectric hafnium oxide layer 24, the polarizations P1 and P2 being anti-parallel. The effect of the oppositely directed polarizations P1 and P2 in the FeFET 10 is that the threshold voltage of the FeFET 10 may be split into two stable states. Accordingly, binary states can be stored in the FeFETs, similar to how it is done in a flash memory cell. The voltages required to switch the FeFET 10 from one state to the other are commonly in the range of 3-5 volts.

FIG. 1c shows a graph of a gate voltage U_{Gate} in arbitrary units and the current U_{Drain} in arbitrary units. The graph of the gate voltage plotted against the drain current U_{Drain} shows a hysteresis curve 30 having a high threshold voltage region 33 and a low threshold voltage region 34.

That is, in case of the FeFET 10 representing an NMOS (i.e., the substrate 1 may have a doping of the P-type and the source/drain regions 5 may have a doping of the N-type), the polarization P1 pointing downward to the channel region 3 attracts minority charge carriers (i.e., electrons) in the channel region 3 such that the threshold voltage of the FeFET 10 shown in FIG. 1a in this example is in the low threshold voltage state 34 of the curve 30 in FIG. 1c. Upon decreasing the gate voltage, the drain current follows the curve 30 in the low threshold voltage state 34 along the direction of arrow 36. Upon increasing the gate voltage to higher gate voltages along arrow 35, the polarization P1 is changed into the polarization P2 illustrated in FIG. 1b, leading to an opposite effect on the minority charge carriers in the channel region 3, and therefore resulting in a higher threshold voltage when compared to the state illustrated in FIG. 1a for the FeFET 10 being of the NMOS type.

In the usual applications, the FeFET 10 of the NMOS type as discussed with regard to FIGS. 1a-1c has the low threshold voltage state 34 at negative gate voltages, therefore resulting in a negative threshold voltage in the memory state of the FeFET 10 shown in FIG. 1a for NMOS. In case of the FeFET 10 being a PMOS device, this is still true, although a high threshold voltage being at positive gate voltage values appears here in one of the memory states. Particularly for NOR flash, this means that one of the memory states has a high current leakage in the off-state such that FeFET may not be applied for NOR flash when power consumption is of concern.

This issue does not appear in NAND memories because, by contrast, a high off-state leakage is not of concern for NAND designs where leakage of program states is not important. Although NAND offers fast write/erase capability when compared to NOR, it is slower than NOR in the area of read speed.

Therefore, it is desirable to provide for FeFETs that allow an application to flash memory by overcoming the high off-state leakage such that FeFET is applicable to both NAND and NOR designs.

### SUMMARY OF THE DISCLOSURE

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

In a first aspect, the present disclosure provides for a semiconductor device structure, including a semiconductor substrate having a first active region formed therein and a first gate structure formed over the first active region. In accordance with some illustrative embodiments herein, the first active region has a doping of a first conductivity type and the gate structure includes a first ferroelectric material and a first gate electrode, wherein the first gate electrode has a first work function of the first conductivity type.

In a second aspect, the present disclosure provides a method including providing a first active region in a semiconductor substrate and forming a first gate structure over the first active region. Herein, the first active region has a doping of a first conductivity type and forming the first gate structure includes forming a first ferroelectric material over the first active region and forming a first gate electrode layer over the first ferroelectric material. In some examples herein, the first gate electrode layer has a first work function of the first conductivity type.

In a third aspect, the present disclosure provides a semiconductor device structure including a semiconductor substrate having a first active region and a second active region formed therein, a first gate structure formed over the first active region and a second gate structure formed over the second active region. In accordance with some illustrative embodiments herein, the first active region has a doping of a P-type and the second active region has a doping of an N-type. Furthermore, the first gate structure includes a first ferroelectric material and a first gate electrode, wherein the first gate electrode has a P-type work function, and the second gate structure includes a second gate electrode and a second ferroelectric material, wherein the second gate structure has an N-type work function.

### BRIEF DESCRIPTION OF THE DRAWINGS

The disclosure may be understood by reference to the following description taken in conjunction with the accompanying drawings, in which like reference numerals identify like elements, and in which:

FIGS. 1a and 1b schematically illustrate a conventional ferroelectric field effect transistor in two memory states;

FIG. 1c schematically illustrates a graph illustrating a relationship between gate voltage and drain current of the conventional field effect transistor shown in FIGS. 1a and 1b;

FIG. 2a schematically illustrates a ferroelectric field effect transistor, in accordance with some illustrative embodiments of the present disclosure;

FIG. 2b graphically represents a cumulative distribution of the threshold voltage of the ferroelectric field effect transistor of FIG. 2a in a program state and an erase state, in accordance with some illustrative embodiments of the present disclosure;

FIG. 3 schematically illustrates a structure having several semiconductor devices, in accordance with some illustrative embodiments of the present disclosure;

FIGS. 4a-4e schematically illustrate band diagrams of a ferroelectric field effect transistor, in accordance with some illustrative embodiments of the present disclosure;

FIG. 4f schematically illustrates a graphical representation of a relationship between charges in the gate electrode and the substrate of ferroelectric field effect transistors, according to various illustrative embodiments of the present disclosure in accumulation, depletion and inversion; and

FIG. 5 schematically illustrates a NOR design, in accordance with some illustrative embodiments of the present disclosure.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase. It is pointed out that any enumeration, such as “a first device/structure/element/component/step/process/layer, etc.” does not necessarily indicate any prioritization or order, but may mainly denote an enumeration of devices/structures/elements/components/steps/processes/layers, etc. that are mentioned, stated or described before at least one other device/structure/element/component/step/process/layer, etc. is mentioned, stated or described as “a second device/structure/element/component/step/process/layer, etc.” and so on.

In various aspects, the present disclosure relates to a semiconductor device structure, wherein the semiconductor device structure is integrated on or in a chip. In accordance with some illustrative embodiments of the present disclosure, the semiconductor device structure may comprise at least one further semiconductor device, e.g., a transistor structure, a capacitor structure and the like.

Semiconductor device structures of the present disclosure may concern structures which are fabricated by using advanced technologies, i.e., the semiconductor device structures may be fabricated by technologies applied to approach technology nodes smaller than 100 nm, for example, smaller than 50 nm or smaller than 35 nm, e.g., at 22 nm or below. After a complete reading of the present application, a person skilled in the art will appreciate that, according to some illustrative examples described herein, ground rules smaller or equal to 45 nm, e.g., at 22 nm or below, may be imposed. After a complete reading of the present application, a person skilled in the art will appreciate that, in some embodiments, the present disclosure proposes capacitor structures having minimal length dimensions and/or width dimensions smaller than 100 nm, for example, smaller than 50 nm or smaller than 35 nm or smaller than 22 nm. For example, the present disclosure may provide structures fabricated by using 45 nm technologies or below, e.g., 22 nm or even below.

The fabrication of semiconductor devices comprises front-end-of-line (FEOL) processing, wherein semiconductor devices may be formed directly in and on a substrate. Herein, a raw wafer may be engineered by the growth of an ultrapure, virtually defect-free silicon layer through epitaxy, for example. Some methods may comprise introducing a straining step wherein a silicon variant, such as silicon-germanium (SiGe) or silicon carbide (SiC), is deposited, resulting in an improved electronic mobility. Another method, called semiconductor-on-insulator (SOI) technology, e.g., silicon-on-insulator, involves the insertion of an insulating layer between a raw wafer and a thin layer of subsequent semiconductor material, resulting in the creation of transistors with reduced parasitic effects. Front-end surface engineering is followed by forming (e.g., growing) a gate dielectric (e.g., silicon dioxide and/or hafnium oxide), forming a gate electrode material on the gate dielectric, patterning of a gate structure, forming source and drain regions, and subsequently implanting and/or diffusing dopants to implement desired electrical properties.

The person skilled in the art will appreciate that, after FEOL processing is completed, so-called “back end of line” (BEOL) processing is performed, wherein metal interconnecting vias that are isolated by dielectric layers are formed in plural metallization layers formed over the substrate, as known in the art.

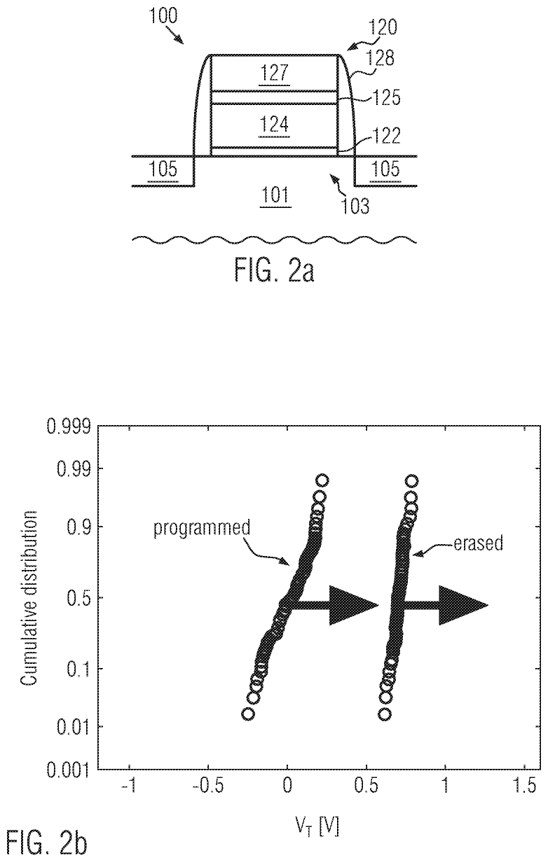

FIG. 2a shows a ferroelectric field effect transistor (FeFET) device structure 100 illustrating a semiconductor device structure in accordance with some illustrative embodiments of the present disclosure, the FeFET device structure 100 comprising a gate structure 120 formed over a semiconductor substrate 101.

In accordance with some illustrative embodiments of the present disclosure, the semiconductor substrate 101 may be a semiconductor bulk substrate or may be an active semiconductor layer of a semiconductor-on-isolator (SOI) configuration, wherein, generally, a semiconductor layer, e.g., silicon, silicon germanium and the like, is formed on a buried insulating material layer, e.g., silicon oxide and the like, which in turn is formed on a substrate material, e.g., a semiconductor bulk substrate and the like. In accordance with some illustrative embodiments, wherein the semiconductor substrate 101 is provided in accordance with SOI techniques, the semiconductor substrate 101 may be partially depleted in accordance with partially depleted SOI (PDSOI) techniques or fully depleted in accordance with fully depleted SOI (FDSOI) techniques, as is known in the art. In accordance with some special illustrative embodiments employing PDSOI techniques or using the semiconductor substrate 101 as a bulk substrate, the semiconductor substrate 101 may be doped, e.g., P-doped or N-doped, and source/drain regions may be implanted into the semiconductor substrate 101 in accordance with known techniques employed at advanced technology nodes using ultra large scale integration (VLSI) processes.

In the semiconductor substrate 101, source/drain regions 105 may be formed, the source/drain regions 105 laterally defining a channel region 103 extending between the source/drain regions 105 within the semiconductor substrate region 101 below the gate structure 120. In accordance with some illustrative embodiments, the semiconductor substrate 101 may have a P-type doping, e.g., lightly P-doped, and the source/drain regions 105 may have an N-type doping, e.g., a strong N-doping. In this case, the FeFET device structure 100 may implement an NMOS device structure. Alternatively, the substrate 101 may have an N-type doping and the source/drain regions 105 may have a P-type doping when implementing the FeFET device structure 100 as a PMOS device. This does not pose any limitation to the present disclosure, and the person skilled in the art will appreciate that a PMOS device may be formed in an N-well provided within a P-type semiconductor substrate and an NMOS device may be provided in a P-well of an N-doped semiconductor substrate. Alternatively, although not illustrated in FIG. 2a, the substrate 101 may be implemented as a silicon-on-insulator (SOI) substrate, wherein the channel region 103 is provided within a silicon layer of the SOI substrate which further comprises a buried isolator formed between the silicon layer and a base substrate (not illustrated). In the case of FDSOI substrates, the source/drain regions 105 may be provided by so-called raised source/drain regions.

The gate structure 120 is formed by a gate stack comprising a gate dielectric and a gate electrode material. In accordance with some illustrative embodiments of the present disclosure, the gate dielectric may comprise a thin gate oxide layer 122, e.g., silicon oxide in the case of a silicon substrate, a high-k material layer and a ferroelectric material 124. The gate electrode material may be formed by at least one gate electrode material, e.g., a gate electrode layer comprising a gate metal and/or polysilicon.

In accordance with some illustrative embodiments of the present disclosure, as illustrated in FIG. 2a by way of example, the gate electrode material may be formed by a gate electrode metal layer 125 and a gate electrode layer 127, e.g., polysilicon. This does not pose any limitation to the present disclosure and the person skilled in the art will appreciate that further material layers may be present, e.g., one or more work function adjusting material layers, e.g., TiN, and/or cap material layers, e.g., a nitride material, although none of these layers is explicitly illustrated.

In accordance with some illustrative embodiments of the present disclosure, in the case that the FeFET device structure 100 implements an NMOS device, the gate electrode material has a work function of the P-type. Alternatively, in the case that the FeFET device structure 100 implements a PMOS device, the gate electrode material has a work function of the N-type. In accordance with some special illustrative and non-limiting examples of the present disclosure, gate electrode metals for NMOS devices may comprise aluminum and/or P-type polysilicon, while gate electrode metals for PMOS devices may comprise lanthanum and/or N-type polysilicon. For example, the electrode metal may be provided such that the gate structure 120 may have a first flat band voltage having an absolute value of at least 0.5 eV with respect to the channel region 103 of the FeFET device structure 100.

With regard to FIG. 2a, the gate structure 120 may further comprise sidewall spacers 128 formed on exposed sidewalls of the gate stack. Furthermore, although not explicitly illustrated in FIG. 2a, halo regions and/or source/drain extension regions and/or raised source/drain regions and/or strain-inducing features may be provided.

The FeFET device structure 100 may be formed by gate first or gate last processing. With regard to gate first processes, the semiconductor substrate 101 may be provided at an early stage during fabrication. At this stage, the semiconductor substrate may have a certain type of doping, e.g., a P-type doping or an N-type doping, or may be undoped. For example, the semiconductor substrate 101 may be subjected to at least one doping process for either implementing a desired overall doping of the semiconductor substrate or forming well regions (not illustrated) within the semiconductor substrate 101 so as to implement well regions within the semiconductor substrate 101. These well regions (not illustrated) may represent local doping regions where the local conductivity type of the substrate may be different from an overall conductivity type of the semiconductor substrate 101. The processes thus described are known in the art and no details are presented in this regard.

The semiconductor substrate 101 may be provided as a bulk semiconductor substrate or an SOI-type semiconductor substrate, e.g., a PDSOI-type substrate or FDSOI-type substrate. Alternatively, the provided semiconductor substrate 101 may be processed for obtaining an SOI-type substrate, e.g., by SIMOX or smart cut processing, which are well known in the art and will not be explained here in detail.

Subsequently, the gate oxide layer 122 may be formed, e.g., by forming a native oxide on an upper surface of the semiconductor surface 101 with a desired thickness.

Subsequently, a ferroelectric dielectric material may be formed on the gate oxide 122. In accordance with some illustrative embodiments of the present disclosure, the ferroelectric dielectric material may be a ferroelectric high-k material, e.g., a ferroelectric material comprising Hf and/or Zr. For example, the ferroelectric dielectric material may be hafnium oxide comprising at least one additional dopant, e.g., Si and/or Al and/or Ge and/or Ng and/or Ca and/or Sr and/or Ba and/or Ti and/or rare earth elements. In accordance with some illustrative examples, a concentration of the one or more additional dopants may be in a range from about 0.2-30 mol %, e.g., in a range from about 0.50-20 mol %.

In a special illustrative example, the ferroelectric gate dielectric may be an HfₐX_{b}O₂ material, wherein X represents one of Zr, Si and Al. In a first explicit example, X may represent Zr and a<0.5, b>0.5. In a second explicit example, X may represent Si and 0.05<b<0.2, 0.88<a<0.95. In an illustrative example herein, b may be further in a range given by 0.05<b<0.12. In a third explicit example, X may represent Al and 0.05<a<0.12, 0.88<b<0.95. The person skilled in the art will appreciate that these explicit examples do not limit the present disclosure, but are provided for illustrative purposes only.

In accordance with some illustrative embodiments of the present disclosure, a ferroelectric dielectric material may be deposited by atomic layer deposition (ALD) or chemical vapor deposition (CVD), for example, in the ferroelectric phase. Alternatively, a ferroelectric phase may be subsequently induced by implantation and/or annealing processes as it is known in the art.

Subsequently, an optional TiN liner (not shown) may be formed on the ferroelectric dielectric material. This does not pose any limitations to the present disclosure and the optional TiN liner may be omitted.

Subsequently, the gate electrode material may be deposited, e.g., a gate metal and/or a polysilicon material. Subsequently, a patterning process may be performed, wherein the gate stack 120 is obtained.

As an alternative to the above-described gate first process, a dummy gate may be provided in gate last processing and the dummy gate may be subsequently replaced by the gate stack 120, i.e., the material layers 124, 125 and/or 127.

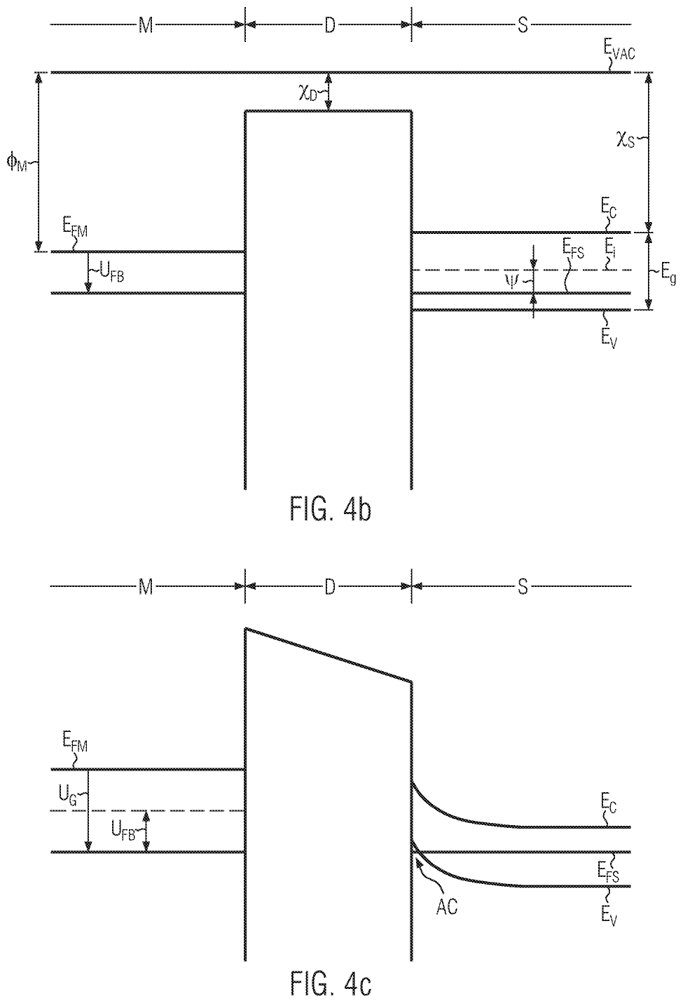

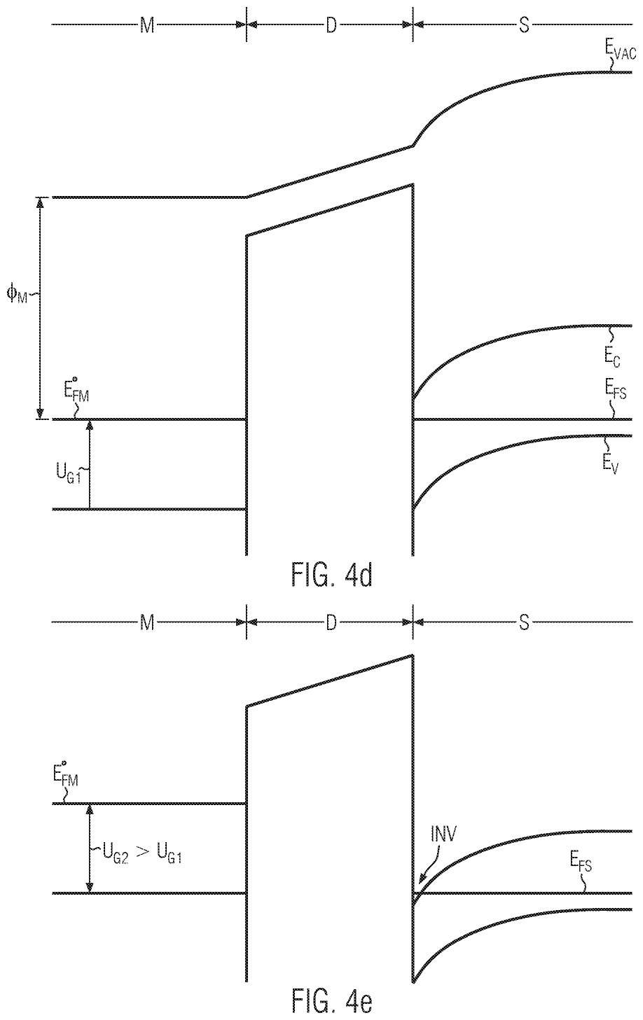

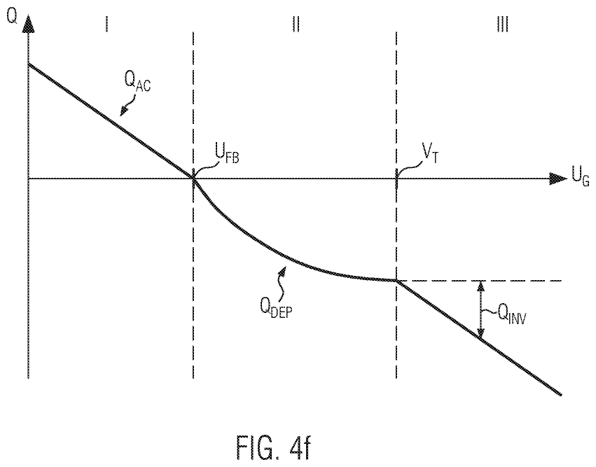

Referring to FIG. 2b, a cumulative distribution of threshold voltages (VT) in the programmed and erased states of gate structures as provided in various illustrative embodiments of the present disclosure is schematically illustrated. As will be explained below with regard to FIGS. 4a-4f in greater detail, a shift in the threshold (VT) may be achieved in the erased and programmed states by implementing the gate structure in accordance with the gate structure 100 described above with regard to FIG. 2a.

After a complete reading of the present disclosure, the person skilled in the art will appreciate that, upon appropriately choosing the gate electrode material of a gate structure with respect to its work function, the electric field of the gate structure induced by the ferroelectric dielectric in the programmed and erased state of a gate structure may be influenced to offset the electrical field by which the gate structure impacts on a channel region present in the substrate material below.

In accordance with some illustrative examples, the gate electrode material may be selected in dependence on the type of transistor to be implemented (NMOS or PMOS) such that the electrical field may be balanced for a certain range in write and erase conditions.

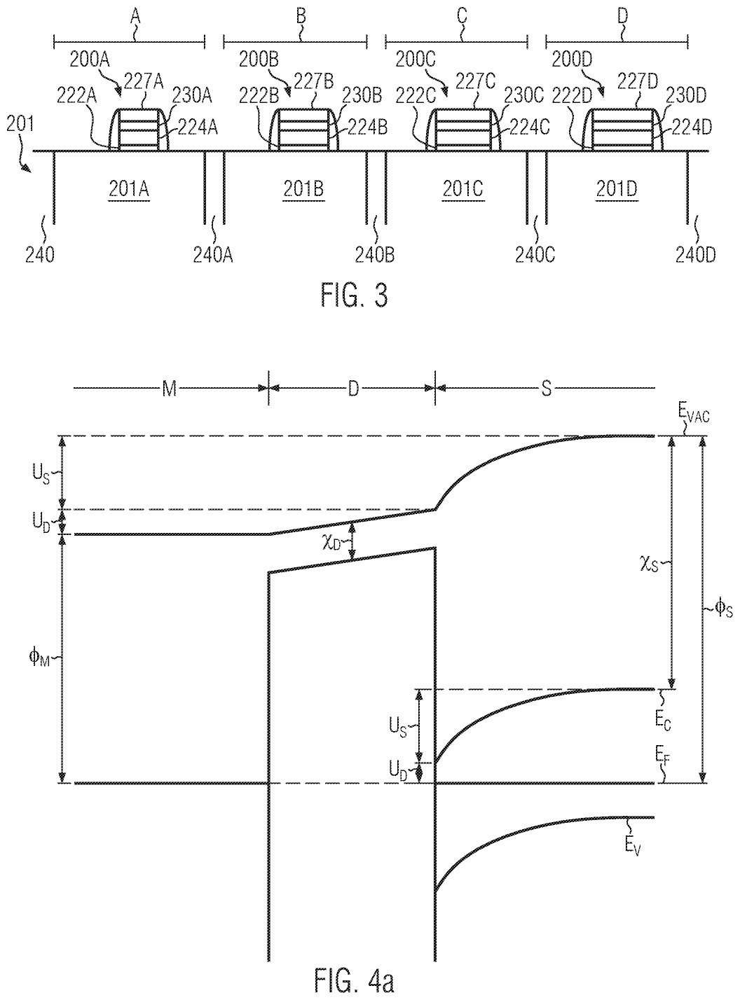

With regard to FIG. 3, a device structure is illustrated. The device structure comprises a semiconductor substrate 201, e.g., similar to the semiconductor substrate 101 as described above with regard to FIG. 2a. Accordingly, further description of the semiconductor substrate 201 is omitted and reference is made to the description presented above with regard to the semiconductor substrate 101.

At an upper surface region of the semiconductor substrate 201, a plurality of active regions may be formed, e.g., four active regions 201A, 201B, 201C and 201D indicating respective device structures A, B, C and D. As shown in FIG. 3, the active regions 201A, 201B, 201C and 201D may be formed as adjacent active regions similar to the illustration in FIG. 3, although this does not pose any limitation to the present disclosure and the person skilled in the art will appreciate that at least one further active region (not illustrated) may be present between each of the active regions 201A, 201B, 201C and 201D.

In accordance with some illustrative embodiments of the present disclosure, trench isolation structures 240, 240A, 240B, 240C and 240D may be formed so as to laterally enclose each of the active regions 201A, 201B, 201C and 201D. For example, the active region 201A may be laterally enclosed by the trench isolation regions 204 and 204A, the active region 201B may be laterally enclosed by the trench isolation regions 240A and 240B, the active region 201C may be laterally enclosed by the trench isolation regions 240B and 240C, and the active region 201D may be laterally enclosed by the trench isolation regions 240C and 240D. This does not pose any limitation to the present disclosure and at least one further trench isolation region (not illustrated) may be present between a given one of the active regions 201A, 201B, 201C, 201D and one of the illustrated trench isolation regions depicted as directly adjacent to the active region under concern. Furthermore, the skilled person will appreciate that the number of active regions is not limited to the explicitly illustrated four active regions and only one active region, or two active regions, or three active regions, or more than four active regions may be provided at the upper surface region of the semiconductor substrate 201.

In and above the active region 201A, the device structure A comprises a gate structure 200A. The gate structure 200A may be formed by a gate oxide layer 222A, a gate dielectric layer 224A, and a gate electrode. In accordance with some illustrative examples herein, the gate electrode may comprise a gate metal layer 230A and a polysilicon layer 227A. This does not pose any limitation to the present disclosure and one of the layers 230A and 227A may be omitted instead.

In and above the active region 201B, the device structure B comprises a gate structure 200B. The gate structure 200B may be formed by a gate oxide layer 222B, a gate dielectric layer 224B, and a gate electrode. In accordance with some illustrative examples herein, the gate electrode may comprise a gate metal layer 230B and a polysilicon layer 227B. This does not pose any limitation to the present disclosure and one of the layers 230B and 227B may be omitted instead.

In and above the active region 201C, the device structure C comprises a gate structure 200C. The gate structure 200C is formed by a gate oxide layer 222C, a gate dielectric layer 224C, and a gate electrode. In accordance with some illustrative examples herein, the gate electrode may comprise a gate metal layer 230C and a polysilicon layer 227C. This does not pose any limitation to the present disclosure and one of the layers 230C and 227C may be omitted instead.

In and above the active region 201D, the device structure D comprises a gate structure 200D. The gate structure 200D is formed by a gate oxide layer 222D, a gate dielectric layer 224D, and a gate electrode. In accordance with some illustrative examples herein, the gate electrode may comprise a gate metal layer 230D and a polysilicon layer 227D. This does not pose any limitation to the present disclosure and one of the layers 230D and 227D may be omitted instead.

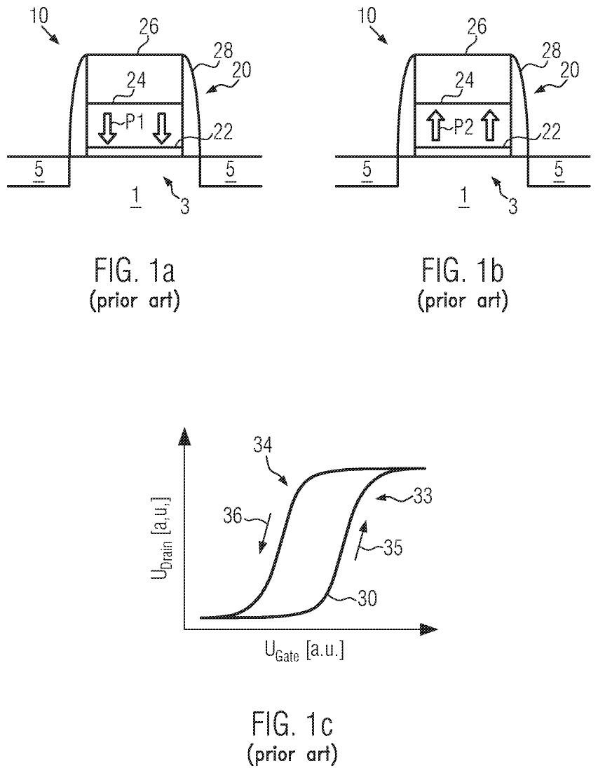

In accordance with some illustrative embodiments of the present disclosure, at least one of the device structures A to D may be implemented in accordance with the FeFET device structure 100 as described above with regard to FIG. 2a. For example, at least one of the device structures A to D may be implemented as a FeFET device structure of a PMOS type as described above with regard to FIG. 2a. Alternatively or additionally, one of the device structures A to D may be implemented as a FeFET device structure of the NMOS type as described above with regard to FIG. 2a by means of the FeFET device structure 100. Additionally or alternatively, at least one of the device structures A to D may be implemented as a conventional FeFET as described above with regard to FIGS. 1a-1c.

In accordance with some illustrative embodiments of the present disclosure, conventional FeFET devices may be provided in the device structure illustrated in FIG. 3 as logic devices, while FeFET device structures, as described above with regard to FIG. 2a, may be provided in accordance with some illustrative embodiments of the present disclosure as memory devices in a flash memory structure (not illustrated). Accordingly, the device structure illustrated in FIG. 3 may realize flash memory devices and/or logic devices which may be implemented in accordance with CMOS technologies at advanced technology nodes.

As will be more clearly understood from the following discussion of FIGS. 4a-4f, the FeFET device structure 100, as described above with regard to FIG. 2a, allows modifying the threshold voltage in such a way that high off-state leakage may be reduced or even avoided. Particularly, in the case of the above-described FeFET device structure 100 implementing an NMOS device structure, the above-described FeFET device structure 100 may have an increased threshold voltage such that, in the low threshold voltage state, the threshold voltage is positive. Similarly, in accordance with an implementation of the FeFET device structure 100 implementing a PMOS device structure, the off-state has a threshold voltage which may be smaller than zero. Accordingly, the off-state leakage may be avoided for NMOS and PMOS type FeFET device structures by providing a FeFET device structure of the PMOS type with a gate electrode having a work function of the N-type and/or providing a FeFET device structure of the NMOS type with a gate electrode having a work function of the P-type.

With regard to FIG. 4a, a band diagram of a metal/dielectric/semiconductor structure in a FeFET device structure is schematically illustrated in accordance with some illustrative embodiments of the present disclosure. This does not pose any limitations in the above disclosure and the person skilled in the art will understand that, instead of a gate electrode metal, polysilicon of the P-type or polysilicon of the N-type may be used. The person skilled in the art will appreciate that the work function of polysilicon of the P-type equals to the electron affinity of polysilicon plus the band gap energy, while the work function of N-type polysilicon equals to the electron affinity of polysilicon. With this in mind, the following discussion may be applied to polysilicon instead of a metal, as well.

FIG. 4a shows the bands in a metal region M, dielectric region D and semiconductor region S. Herein, the metal region M corresponds to one of the gate electrode layers 125 and 128 in FIG. 2a having an interface with the (ferroelectric) gate dielectric. The dielectric region D corresponds to the gate dielectric layer 124 in FIG. 2a and the semiconductor region S corresponds to the semiconductor substrate in FIG. 2a.

In the schematic illustration of FIG. 4a, the unperturbed or flat band vacuum energy E_{VAC} is indicated as a reference by a dashed line. The situation illustrated in FIG. 4a may be understood as corresponding to the case that no gate voltage is applied to the FeFET device structure shown in FIG. 2a.

Generally, the work function of the metal M is the difference between the Fermi level E_{F} and the vacuum energy E_{VAC} and represents a fixed characteristic of the surface of the metal M. Referring to the dielectric D, the dielectric D is characterized by its electron affinity and a very large band gap in the range of several eV, such as a band gap of about 9 eV in the case of silicon oxide. The electron affinity of silicon oxide is, for example, about 0.9 eV. With regard to the term “electron affinity,” this term is generally understood in solid state physics as indicating the difference between the vacuum energy E_{VAC} and the conduction band. The expression “band gap” usually denotes in solid state physics the difference between the conduction band and the valance band of a material. Therefore, as the electron affinity and the work function are characteristics of a material and, thus, represent constants, differences between the respective levels of conductive band and the Fermi level with respect to the vacuum energy E_{VAC} are constant. However, due to a difference between the work function Φₘ of the metal M and the work function Φ_{S} of the semiconductor S, a bending of bands appears, leading to the curved reference line indicating the vacuum energy E_{VAC} with respect to the shared Fermi level E_{F} of the metal M and the semiconductor S. With regard to the dielectric D, it is assumed that there are no charges in the dielectric, which thus acts as an isolator.

As shown in FIG. 4a, the conduction band E_{C} of the semiconductor S and the valance band E_{V} of the semiconductor S are curved with respect to the Fermi level E_{F}. By way of example, when assuming an NMOS device structure having a P-type silicon substrate (the electron affinity X_{S} equals 4.1 eV, the band gap of silicon equals 2.12 eV, the work function of silicon Φ_{S} is assumed to lie between 4.66 eV and 5.22 eV, e.g., 4.9 eV in the case of an acceptor doping N_{A}=1.1×10¹⁵ cm³ in aluminum, and the work function Φₘ of Al equals 4.0 eV), the difference in the work function results in the bending of the bands as illustrated in FIG. 4a. The illustration in FIG. 4a is not to scale.

The bending of the bands may be understood as follows. With regard to the illustration of FIG. 4a, although there is no movement of charge carriers through the dielectric D, a positive charge accumulates at the interface between the metal M and the dielectric D, while a negative charge of equal absolute magnitude is present in the depletion region at the interface between the dielectric D and the semiconductor S. Accordingly, the bending of the conduction and valance bands E_{C} and E_{V} occurs despite no voltage being applied to the metal M. From the condition Φ_{M}+U_{D}+U_{S}=Φ_{S}, it follows that the difference between the work function of the metal and the work function of the semiconductor is given by Φ_{S}−Φ_{M}=U_{D}+U_{S}. Herein, the quantity U_{D} is proportional to the voltage drop over the dielectric D and the quantity U_{S} is proportional to the voltage drop over the depletion region in the semiconductor S. In the example of the metal M being aluminum and the semiconductor S being of P-type silicon, the voltage drops over the oxide and the semiconductor are typically about 0.4 volts. It is noted that the Fermi level E_{F} and the conduction band E_{C} in the semiconductor S do not overlap. Accordingly, no inversion yet occurs in the case of FIG. 4a.

With regard to FIG. 4b (the illustration in FIG. 4b is not to scale), a flat band diagram corresponding to FIG. 4a is schematically illustrated. In order to obtain the flat band diagram depicted in FIG. 4b, when starting from the situation illustrated in FIG. 4a, a negative voltage, the so-called “flat band voltage,” is to be applied to the metal M. The flat band voltage is indicated in FIG. 4b by U_{FB} (wherein a factor e is suppressed). The negative flat band voltage is indicated by the orientation of the arrow indicated by U_{FB} in FIG. 4b. In other words, application of the negative flat band voltage U_{FB} “lifts” the Fermi level of the metal M (now indicated by E_{FM} in FIG. 4b) relative to the Fermi level in the semiconductor S (indicated by E_{FS} in FIG. 4b). In addition, the illustration in FIG. 4b shows the gap E_{G} between the conduction band E_{C} and the valance band E_{V} in semiconductor S. The shift of the Fermi level E_{FS} relative to the intrinsic Fermi level E_{E} of the semiconductor S as obtained by P-type doping is indicated by Ψ. It is indicated that an N-type doping would occur by shifting the Fermi level E_{FS} in the region between the conductive band E_{C} and the intrinsic Fermi level Eᵢ. According to the case in FIG. 4b, the condition Φ_{M}−U_{FB}=Φ_{S} (i.e., in the notation of FIG. 4b: Φ_{S}=X_{S}+E_{g}/2+Ψ) is valid, indicating that no charges are present at the interfaces and no voltage drop occurs at the dielectric D in the semiconductor S.

With regard to FIG. 4c (the illustration in FIG. 4c is not to scale), for the sake of completeness, a situation is illustrated where a negative voltage U_{G}<U_{FB} (“more negative than the flat band voltage”) is applied to the metal M, leading to a further lift of the Fermi level E_{FM} of the metal M relative to the Fermi level E_{FS} of the semiconductor S. Accordingly, bending of the conduction band E_{C} in the valance band E_{V} of the semiconductor S as indicated in FIG. 4c occurs and an accumulation of holes is generated at the interface of the semiconductor S in the dielectric D, which is indicated in FIG. 4c with reference numeral AC (the valance band E_{V} overlaps the Fermi level E_{FS} of the semiconductor S).

With regard to FIG. 4d (the illustration in FIG. 4d is not to scale), a situation is illustrated where a positive voltage U_{G1} is applied to the metal M. The application of the positive voltage U_{G1} to the metal M lowers the level of energy in the metal Φ_{M} relative to the Fermi level in FIG. 4a indicated now by E⁰_{FM} in FIG. 4d, leading now to the condition U_{G1}=Φ_{M}+U_{D}+U_{S}−Φ_{S} (when applying the notation of FIG. 4a). According to the illustration in FIG. 4d, the gate voltage U_{G1} had the effect of increasing the diffusion voltage in the semiconductor S, resulting in a further depletion of the semiconductor S to be free of majority charge carriers, as opposed to FIG. 4a. Accordingly, FIG. 4d shows the depletion state of the metal/dielectric/semiconductor junction.

Upon further increasing the gate voltage by applying a gate voltage U_{G2}>U_{G1} as shown in FIG. 4d, a further bending of the conductive band E_{C} and E_{V} in the semiconductor S is achieved, resulting in an intersection of the conductive band E_{C} and the Fermi level E_{FS}. Accordingly, provided that U_{G2} is greater than the threshold voltage (which is assumed in the illustration of FIG. 4e), an inversion takes place as indicated by reference numeral INV in FIG. 4e (the illustration in FIG. 4e is not to scale).

The outcome of the band diagrams as depicted in FIGS. 4a-4e is summarized in the diagram depicted in FIG. 4f (the illustration in FIG. 4f is not to scale) showing a graphical representation of the charge Q in the semiconductor S during accumulation (indicated by region I), depletion (indicated by region II) and inversion (indicated by region III). Particularly, the graphical illustration indicated in FIG. 4f shows that the charge in the semiconductor substrate S, i.e., the majority charge carriers indicated by the line Q_{AC}, decreases (actually linearly with an inclination proportional to the capacity of the dielectric D) towards the flat band voltage U_{FB} at the transition between accumulation in region I and depletion in region II. Upon further increasing the voltage at the gate beyond the flat band voltage U_{FB}, the minority charges in the semiconductor S increase as indicated by Q_{DEP} in region II of the diagram in FIG. 4f. It is noted that the graph of the accumulation charge Q_{AC} is zero outside the region I. At the threshold voltage V_{T} in the transition between the regions II and III in FIG. 4f, inversion takes place and the inversion charge Q_{INV} increases linearly, basically proportional to the capacity of the dielectric D. As the inclinations of the charges Q_{AC} in region I and Q_{INV} in region III increase linearly depending on the capacity of the dielectric D (which is in approximation not dependent on the gate voltage in regions I and III), a shift in the flat band voltage U_{FB} effects the threshold voltage V_{T}. Particularly, upon increasing the flat band voltage U_{FB}, the threshold voltage V_{T} is increased. The inventors understood that the threshold voltage of the FeFET device structure 100, as discussed with regard to FIG. 2a in the case of an NMOS type device structure, may be increased when implementing the gate electrode with a work function of the P-type. In other words, the threshold voltage V_{T} may be increased by appropriately selecting a suitable gate electrode having an appropriate work function with respect to the Fermi level of the substrate. Accordingly, the threshold voltage of a FeFET device structure of the PMOS type may be lowered by appropriately matching the gate electrode with the substrate, i.e., selecting a gate electrode having a work function of the N-type with the semiconductor substrate having a doping of the N-type.

After a complete reading of the present disclosure, the person skilled in the art will appreciate that a gate electrode material may be selected for appropriately adjusting the work function of a gate structure. For example, the gate electrode material may be chosen to implement write and erase operations, where the electrical fields (in the following “Vgs” is the gate-source voltage and “tox” is the thickness of the gate dielectric, e.g., gate oxide) are proportional to: (i) (Vgs+Φ_{M}−Φ_{S})/tox, where the work function Φ_{S} represents the work function in accumulation (see FIG. 4c), and (ii) (Vgs+Φ_{M}−Φ_{S})/tox, where the work function Φ_{S} represents the work function in inversion (see FIG. 4e). The cases (i) and (ii) show how the work functions of a gate electrode material and a gate dielectric material may lead to an offset in the electric field present between gate and channel during write and erase operation. Accordingly, as described above with regard to FIG. 2b, a shift in the threshold voltage during write and erase operations may be achieved, e.g., the threshold voltage of an NMOS implementation may be shifted to positive values during write operations or in the programmed state.

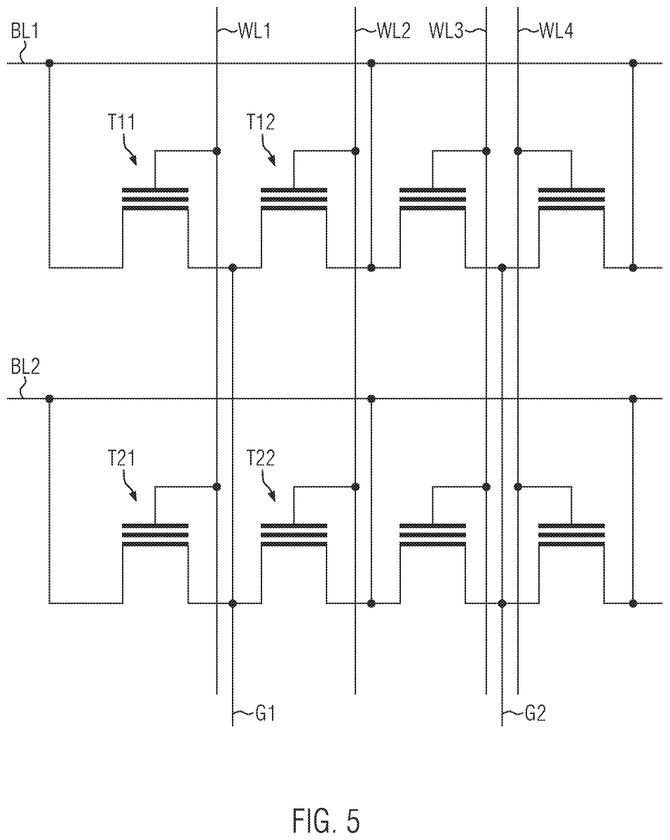

FIG. 5 shows a NOR layout in accordance with some illustrative embodiments of the present disclosure. The illustrative NOR layout shown in FIG. 5 has a first bit line BL1 and a second BL2. This does not pose any limitation to the present disclosure and any number of bit lines may be realized, e.g., a single bit line or more than two bit lines. Furthermore, the NOR layout shown in FIG. 5 has four word lines, a first word line WL1, a second word line WL2, a third word line WL3 and a fourth word line WL4. This does not pose any limitation to the present disclosure and the person skilled in the art will appreciate that any other number of word lines may be realized, e.g., a single word line, two word lines, three word lines, or more than four word lines. The first bit line BL1 is coupled with a number of ferroelectric transistor structures, the number of FeFETs matching the number of word lines. Similarly, the second bit line BL2 is coupled with a number of FeFETs matching the number of word lines.

In a special illustrative example, the layout illustrated in FIG. 5 is implemented as a NOR layout of the NMOS type. Accordingly, FeFETs of NMOS type are provided, such as T11, T12 electrically coupled in series such that the source of each of T11 and T12 are coupled with the first bit line BL1, while the FeFETs T11 and T12 are coupled via their drains, e.g., share a common drain. The shared or common drain of the FeFETs T11 and T12 are connected to a common potential line G, e.g., ground. Similarly, FeFETs T21 and T22 are coupled with the second bit line BL2 and the drain line G.

The gate structures of the FeFETs T11 and T21 are coupled to the first word line WL1. Similarly, the gate structures of the FeFETs T12 and T22 are coupled to the second word line WL2. Upon employing FeFETs, as described above with regard to FIGS. 2a-4f, a leakage in the off-state of the FeFETs of the NOR layout shown in FIG. 5 from one of the bit lines BL1, BL2 to one of the drain lines G1 and G2 is suppressed.

After a complete reading of the present disclosure, the person skilled in the art will appreciate that the present disclosure enables parallel designs using FeFET bit cells due to reduced or even suppressed off-state leakage, thereby improving the read current. Particularly, as indicated in FIG. 2b of the present disclosure, the threshold voltage in the program state of NMOS type FeFETs may be increased. It is understood in the context of the present disclosure that the gate work function of a FeFET is a key variable with regard to the threshold voltage of the FeFET. For example, a gate electrode having a P-type work function may increase the threshold voltage, leading to advantages in the usage of embedded flash memory. Accordingly, a IT ferroelectric bit cell with low leakage in program state for flash NOR design may be obtained.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1.-7. (canceled)

8. A method, comprising:
forming a first gate structure over a first active region in a semiconductor substrate, said first active region having a doping of a first conductivity type;
forming first source/drain regions adjacent said first gate structure having a doping of a second conductivity type opposite said first conductivity type, wherein forming said first gate structure comprises:
forming a first ferroelectric material over said first active region; and
forming a first gate electrode layer over said first ferroelectric material, said first gate electrode layer having a first work function of said first conductivity type.

9. The method of claim 8, further comprising:
forming a second gate structure over a second active region in said semiconductor region, said second active region having a doping of said second conductivity type;
forming second source/drain regions adjacent said second gate structure having a doping of said first conductivity type, wherein forming said second gate structure comprises:
forming a second ferroelectric material over said second active region; and
forming a second gate electrode layer over said second ferroelectric material, said second gate electrode layer having a second work function of said second conductivity type.

10. The method of claim 9, wherein said first conductivity type is a P-type.

11. The method of claim 10, wherein forming said first gate electrode layer comprises depositing one of aluminum and P-type polysilicon.

12. The method of claim 9, wherein said second conductivity type is an N-type.

13. The method of claim 12, wherein forming said second gate electrode layer comprises depositing one of lanthanum and N-type polysilicon.

14. The method of claim 9, wherein at least one of said first gate structure and said second gate structure has a first flat band voltage having an absolute value of at least 0.5 eV.

15. The method of claim 8, further comprising:
forming a second gate structure over a second active region in said semiconductor region, said second active region having a doping of said second conductivity type;
forming second source/drain regions adjacent said second gate structure having a doping of said first conductivity type, wherein forming said second gate structure comprises:
forming a second ferroelectric material over said second active region; and
forming a second gate electrode layer over said second ferroelectric material, said second gate electrode layer having a second work function of said first conductivity type.

16. The method of claim 8, wherein forming said first ferroelectric material comprises:
depositing a metal material layer comprising one of aluminum and lanthanum over a first material layer;
performing an anneal process for diffusing metal material of said metal material layer into said first material layer; and
removing excess material of said metal material layer.

17. The method of claim 16, further comprising:
depositing a TiN material layer over said first ferroelectric after said excess material is removed;
depositing a polysilicon material layer over said TiN material layer; and
performing a shaping process for forming said first gate structure.

18. The method of claim 9, wherein forming said second ferroelectric material comprises:
depositing a metal material layer comprising one of aluminum and lanthanum over a second material layer;
performing an anneal process for diffusing metal material of said metal material layer into said second material layer; and
removing excess material of said metal material layer.

19. The method of claim 18, further comprising:
depositing a TiN material layer over said second ferroelectric after said excess material is removed;
depositing a polysilicon material layer over said TiN material layer; and
performing a shaping process for forming said second gate structure.

20. (canceled)

21. A method, comprising:
forming a first gate structure over a first active region in a semiconductor substrate, said first active region having a P-type doping;
forming first source/drain regions adjacent said first gate structure having an N-type doping, wherein forming said first gate structure comprises forming a first ferroelectric material over said first active region and forming a first gate electrode layer over said first ferroelectric material, said first gate electrode layer comprising P-type polysilicon;
forming a second gate structure over a second active region in said semiconductor region, said second active region having an N-type doping; and
forming second source/drain regions adjacent said second gate structure having a P-type doping, wherein forming said second gate structure comprises forming a second ferroelectric material over said second active region and forming a second gate electrode layer over said second ferroelectric material, said second gate electrode layer comprising N-type polysilicon.

22. The method of claim 21, wherein forming said first gate electrode layer comprises depositing aluminum.

23. The method of claim 22, wherein forming said second gate electrode layer comprises depositing lanthanum.

24. The method of claim 21, wherein at least one of said first gate structure and said second gate structure has a first flat band voltage having an absolute value of at least 0.5 eV.

25. The method of claim 21, further comprising:
forming a third gate structure over a third active region in said semiconductor region, said third active region having an N-type doping;
forming third source/drain regions adjacent said third gate structure having a P-type doping, wherein forming said second gate structure comprises:
forming a third ferroelectric material over said third active region; and
forming a third gate electrode layer over said third ferroelectric material, said third gate electrode layer having a P-type work function.

26. The method of claim 21, wherein forming said first ferroelectric material layer comprises:
depositing a metal material layer comprising aluminum over a first material layer;
performing an anneal process for diffusing metal material of said metal material layer into said first ferroelectric material layer; and
removing excess material of said metal material layer.

27. The method of claim 26, further comprising:
depositing a TiN material layer over said first ferroelectric after said excess material is removed;
depositing a polysilicon material layer over said TiN material layer; and
performing a shaping process for forming said first gate structure.

28. The method of claim 26, wherein forming said second ferroelectric material gate electrode layer comprises:
depositing a metal material layer comprising lanthanum over said a second material layer;
performing an anneal process for diffusing metal material of said metal material layer into said second material layer; and
removing excess material of said metal material layer.
